(19) United States
(12) Patent Application Publication
(10) Pub. No.: US 2018/0184524 A1
(43) Pub. Date: Jun. 28, 2018

(54) MIXED BALL GRID ARRAY PITCH FOR INTEGRATED CIRCUIT PACKAGE

(71) Applicant: Innovium, Inc., San Jose, CA (US)

(72) Inventor: Yongming Xiong, Fremont, CA (US)

(21) Appl. No.: 15/391,254

(22) Filed: Dec. 27, 2016

(51) Int. Cl. H05K 1/18; H01L 23/498; H05K 1/11; H05K 1/02

(52) U.S. Cl. CPC H05K 1/181; H01L 23/49816; H01L 23/498; H05K 1/115; H01L 23/49827; H05K 1/111; H05K 1/0245; H01L 23/49838

(57) ABSTRACT

An integrated circuit package including a substrate; an integrated circuit chip arranged on the substrate; and a ball grid array configured to electrically and mechanically connect a printed circuit board and the substrate, the ball grid array including: first solder balls that are periodically separated by a first pitch; and second solder balls that are periodically separated by a second pitch that is smaller than the first pitch, where a size of each solder ball of the first solder balls is substantially equal to a size of each solder ball of the second solder balls.

### BACKGROUND

This specification relates to forming an electrical connection with a printed circuit board through a ball grid array.

### SUMMARY

An integrated circuit (IC) chip, such as an application-specific integrated circuit (ASIC) chip, may be attached on top of a substrate to be packaged with solder balls in order to establish electrical connections with a printed circuit board (PCB). Circuitry on such a package may be used in transferring data in data networks, data centers, and many other suitable applications. For high-speed applications, such as serializer/deserializer (SerDes) input/output (I/O) in networking switch ASIC chips, electrical connections with the PCB may be established using flip chip ball grid array (FCBGA), where the chip die is flip-chip bonded to one side of the substrate while solder balls are attached to the other side of the substrate using solder balls that are periodically spaced by a predetermined pitch. There is a continuing need to increase the ASIC SerDes I/O numbers to meet the increasing internet data demand and data bandwidth demand. This leads to a continuing need to increase the number of BGA solder balls in a package to accommodate the I/O increase demand. With the I/O bandwidth becoming higher, its corresponding core logic is increased accordingly to process the increase in data bandwidth. This leads to a larger core logic power requirement, and more power BGA balls are required to prevent electro-migration and to lower voltage drop. However, the BGA solder ball counts are limited by the package size. The package size is limited by manufacturing issues such as substrate warpage, solder ball co-planarity, and the yield of the assembly process.

Lowering the BGA pitch is one way to get more BGA balls in a limited-sized package. However, a small BGA pitch may not be suitable for a SerDes I/O chip or other chips having a large count of differential pairs. The high I/O-count ASIC is typically used on large size PCB and thick PCB applications, where a small pitch BGA may be very difficult for PCB manufacturing and PCB assembling process due to mis-registration and tolerance of a large size PCB from manufacturing process and large PCB assembling process. In addition, small pitch BGA signal escape becomes difficult inside BGA field, where the crosstalk between differential pairs increases as the BGA pitch decreases, assuming differential pairs have the same trace impedance using a same PCB stack-up. Generally, if the BGA pitch is large enough, an escape routing scheme may be used to route traces between two rows/columns of vias to avoid or to reduce crosstalk between two differential pairs on a same PCB layer. However, a small BGA pitch prevents the signal traces of a differential pair from being routed on the same PCB layer as another differential pair, and therefore requires adding more PCB routing layers, which causes an increase in PCB cost. Laser vias or micro-vias may help ease the PCB signal escaping, but the cost is higher and the reliability is not lower than plating through hole via (PTH). Lowering the BGA pitch also means that a smaller BGA ball size has to be used. However, to maintain the same kind of current capacity as the large pitch BGA, the smaller pitch BGA option has to assign more power balls and GND balls for high power. As the result, lowering BGA pitch may not necessarily increase the signal BGA density linearly.

According to one innovative aspect of the subject matter described in this specification, a smaller BGA pitch is assigned to a region of the substrate where BGA balls are used to provide power signals, ground signals, and/or low-speed I/O signals between the substrate and the PCB. By assigning a smaller BGA pitch to such a region, more same size BGA balls may be added to the region and the BGA ball density in a package may be increased therefore the current capacity of the package could be increased. By maintaining a larger BGA pitch to other regions, in particular, to regions where high-speed I/O signals are provided, good high speed I/O performance of the package is maintained. Moreover, BGA balls for one or more high speed differential pairs may be added to the region having the smaller BGA pitch if these high speed differential pairs correspond to the inner-most differential pairs in an escape routing scheme.

In general, one innovative aspect of the subject matter described in this specification can be embodied in an integrated circuit package that includes a substrate comprising a multilayer lamination of ground layers, power layers and signal layers; an integrated circuit chip arranged on the substrate; and a ball grid array configured to electrically and mechanically connect a printed circuit board and the substrate. The ball grid array includes first solder balls that are periodically separated by a first pitch, where two solder balls of the first solder balls connect a first pair of differential signals between the printed circuit board and the substrate; and second solder balls that are periodically separated by a second pitch that is smaller than the first pitch, where two solder balls of the second solder balls connect a second pair of differential signals between the printed circuit board and the substrate, where a size of each solder ball of the first solder balls is substantially equal to a size of each solder ball of the second solder balls.

This and other implementations can each optionally include one or more of the following features. The first solder balls may be arranged outside a perimeter of the integrated circuit chip. The second solder balls may be arranged within the perimeter of the integrated circuit chip. The first solder balls and the second solder balls may be arranged outside a perimeter of the integrated circuit chip.

One or more solder balls of the second solder balls may supply power between the printed circuit board and the integrated circuit chip. One or more other solder balls of the second solder balls may supply a ground signal between the printed circuit board and the integrated circuit chip.

The first pitch may be larger than a signal routing spacing threshold. The signal routing spacing threshold may be a sum of (i) a width of a first signal trace carrying a first signal of the first pair of differential signals, (ii) a width of a second signal trace carrying a second signal of the first pair of differential signals, (iii) a minimum separation between the first signal trace and the second signal trace, (iv) a minimum distance from the first signal trace to a first via that is adjacent to the first signal trace, (v) a minimum distance from the second signal trace to a second via that is adjacent to the second signal trace, (vi) a radius of the first via, and (vii) a radius of the second via. The first via may be a conductive via and the second via is a back-drilled via. The second pitch may be smaller than the signal routing spacing threshold.

The first solder balls may be arranged on intersections of a first square or rectangular grid having the first pitch. The second solder balls may be arranged on intersections of a second square or rectangular grid having the second pitch.

Another innovative aspect of the subject matter described in this specification can be embodied in an integrated circuit package that includes a substrate; an integrated circuit chip arranged on the substrate; and a ball grid array configured to electrically and mechanically connect a printed circuit board and the substrate. The ball grid array includes first solder balls that are periodically separated by a first pitch, where the first solder balls are arranged outside a boundary of the integrated circuit chip, and where the first solder balls are arranged on intersections of a first square grid having the first pitch; and second solder balls that are periodically separated by a second pitch that is smaller than the first pitch, where the second solder balls are arranged within the boundary of the integrated circuit chip, and where the second solder balls are arranged on intersections of a second square or rectangular grid having the second pitch. A size of each solder ball of the first solder balls is substantially equal to a size of each solder ball of the second solder balls.

This and other implementations can each optionally include one or more of the following features. Two solder balls of the first solder balls may connect a first pair of differential signals between the printed circuit board and the substrate. Two solder balls of the second solder balls may connect a second pair of differential signals between the printed circuit board and the substrate.

The first pitch may be larger than a signal routing spacing threshold. The signal routing spacing threshold may be a sum of (i) a width of a first signal trace carrying a first signal of the first pair of differential signals, (ii) a width of a second signal trace carrying a second signal of the first pair of differential signals, (iii) a minimum separation between the first signal trace and the second signal trace, (iv) a minimum distance from the first signal trace to a first via that is adjacent to the first signal trace, (v) a minimum distance from the second signal trace to a second via that is adjacent to the second signal trace, (vi) a radius of the first via, and (vii) a radius of the second via. The first via may be a conductive via and the second via is a back-drilled via. The second pitch may be smaller than the signal routing spacing threshold.

The first solder balls may be arranged outside a perimeter of the integrated circuit chip. The second solder balls may be arranged within the perimeter of the integrated circuit chip. The first solder balls and the second solder balls may be arranged outside a perimeter of the integrated circuit chip.

Another innovative aspect of the subject matter described in this specification can be embodied in apparatus that includes a printed circuit board including multilayer lamination of ground layers, power layers and signal layers; bonding pads for a ball grid array of an integrated circuit package. The bonding pads include first periodic bond pads that are periodically separated by a first pitch, where two bond pads of the first bond pads are configured to connect a first pair of differential signals between a printed circuit board and the integrated circuit package; and second periodic bond pads that are periodically separated by a second pitch that is smaller than the first pitch, where two bond pads of the second bond pads connect a second pair of differential signals between the printed circuit board and the integrated circuit package.

This and other implementations can each optionally include one or more of the following features. The apparatus may include an integrated circuit package including a substrate including a multilayer lamination of ground layers, power layers and signal layers; an integrated circuit chip arranged on the substrate; and a ball grid array configured to electrically and mechanically connect the printed circuit board and the substrate. The ball grid array may include first solder balls that are periodically separated by the first pitch; and second solder balls that are periodically separated by the second pitch, where a size of each solder ball of the first solder balls is substantially equal to a size of each solder ball of the second solder balls.

The first pitch may be larger than a signal routing spacing threshold. The signal routing spacing threshold may be a sum of (i) a width of a first signal trace carrying a first signal of the first pair of differential signals, (ii) a width of a second signal trace carrying a second signal of the first pair of differential signals, (iii) a minimum separation between the first signal trace and the second signal trace, (iv) a minimum distance from the first signal trace to a first via that is adjacent to the first signal trace, (v) a minimum distance from the second signal trace to a second via that is adjacent to the second signal trace, (vi) a radius of the first via, and (vii) a radius of the second via. The first via may be a conductive via and the second via may be a back-drilled via. The second pitch may be smaller than the signal routing spacing threshold.

The first bond pads may be arranged on intersections of a first square or rectangular grid having the first pitch, and the second bond pads may be arranged on intersections of a second square or rectangular grid having the second pitch.

The subject matter described in this specification can be implemented in particular embodiments so as to realize one or more of the following advantages. By assigning a smaller pitch with the same BGA ball size to a die shadow area, extra space may be created to add additional BGA balls, e.g., power and GND balls, to increase BGA density in a ball-count limited package. The area with a smaller pitch has power balls that are more densely arranged, and the dense arrangement may prevent electro-migration and may reduce a voltage drop. The smaller pitch may be assigned to most inner differential pairs without the same spacing constraints for routing outer differential pairs. Therefore, more differential pairs may be added to a ball-count limited package without limiting the PCB signal escaping or introducing crosstalk degradation for high speed signals. Selectively assigned mixed BGA ball pitch assignment enables similar BGA counts in a smaller package size.

The detail of one or more implementations are set forth in the accompanying drawings and the description below. Other features, aspects, and advantages will become apparent from the description, the drawings, and the claims.

### BRIEF DESCRIPTION OF THE DRAWINGS

FIGS. 1A and 1B illustrate an example integrated circuit package having a ball grid array with different BGA pitches.

FIG. 2 illustrates an example printed circuit board region having a standard BGA pitch.

FIG. 3 illustrates an example printed circuit board region having a smaller BGA pitch.

FIG. 4 illustrates an example printed circuit board region having different BGA pitches.

Like reference numbers and designations in the various drawings indicate like elements. It is also to be understood that the various exemplary embodiments shown in the figures are merely illustrative representations and are not necessarily drawn to scale.

### DETAILED DESCRIPTION

In general, a count of ball grid array (BGA) solder balls is directly correlated to a BGA pitch and a package size. Table 1 below illustrates a BGA ball count for various package sizes and BGA pitches for conventional ball grid arrays.

TABLE 1
BGA ball count for various square package sizes and BGA pitches for
conventional BGAs.

| Package Size (mm) | BGA Pitch (mm) | BGA Ball Counts |
|---|---|---|
| 35 | 0.8 | 1764 |
| 37.5 | 0.8 | 2025 |
| 40 | 1 | 1521 |
| 42.5 | 1 | 1681 |
| 45 | 1 | 1936 |
| 47.5 | 1 | 2116 |
| 50 | 1 | 2401 |
| 52.5 | 1 | 2601 |
| 55 | 1 | 2916 |
| 57.5 | 1 | 3136 |
| 60 | 1 | 3481 |
| 62.5 | 1 | 3721 |
| 65 | 1 | 4096 |

In general, for a single pitch, a BGA ball count for a conventional BGA may be calculated as:

$$BGA Count = \frac{( w - x ) \cdot ( l - y )}{{P}^{2}} , \qquad ( 1 )$$

where w and l are the width and length of the package, respectively, x and y are the reserved space (e.g., 1 mm in Table 1), and P is the BGA pitch.

As described in more detail below, a mixed-pitch BGA includes solder balls with more than one pitch, such that the overall BGA density of an integrated circuit (IC) package may be increased without negatively impacting the high speed performance of the IC package. Note that regardless of the associated pitch, the solder balls in the mixed-pitch BGA have to be the same size or substantially the same size, i.e., within a predefined tolerance range that does not affect the co-planar characteristic of the IC package.

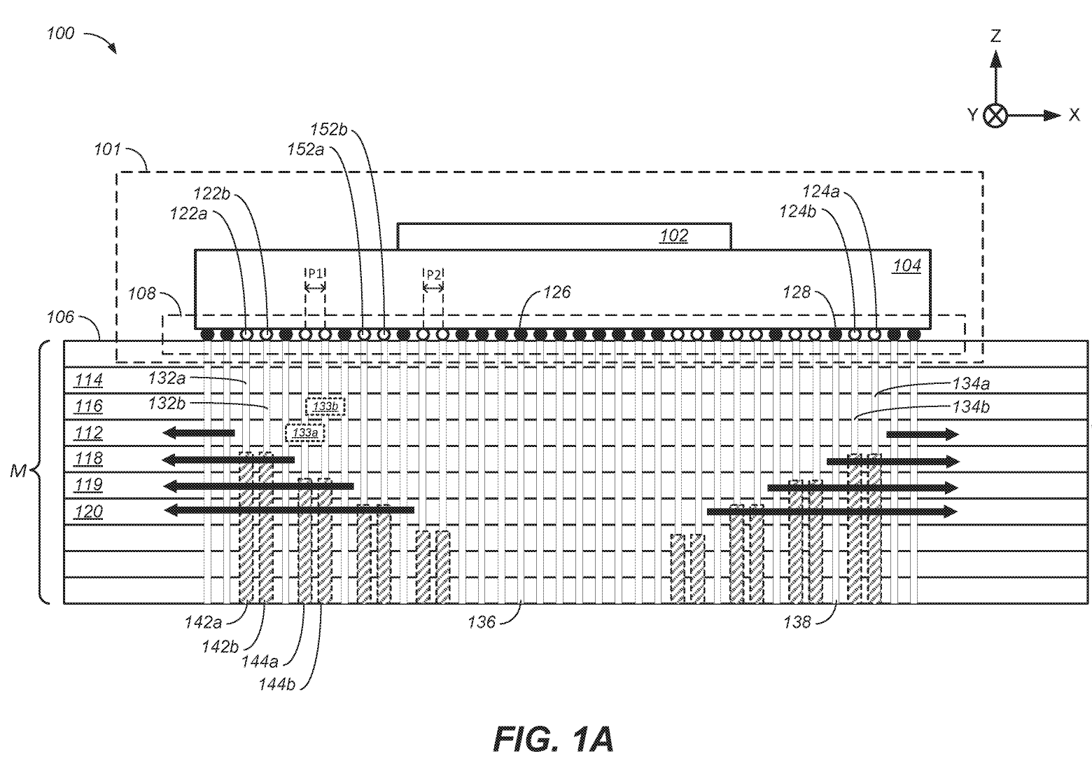

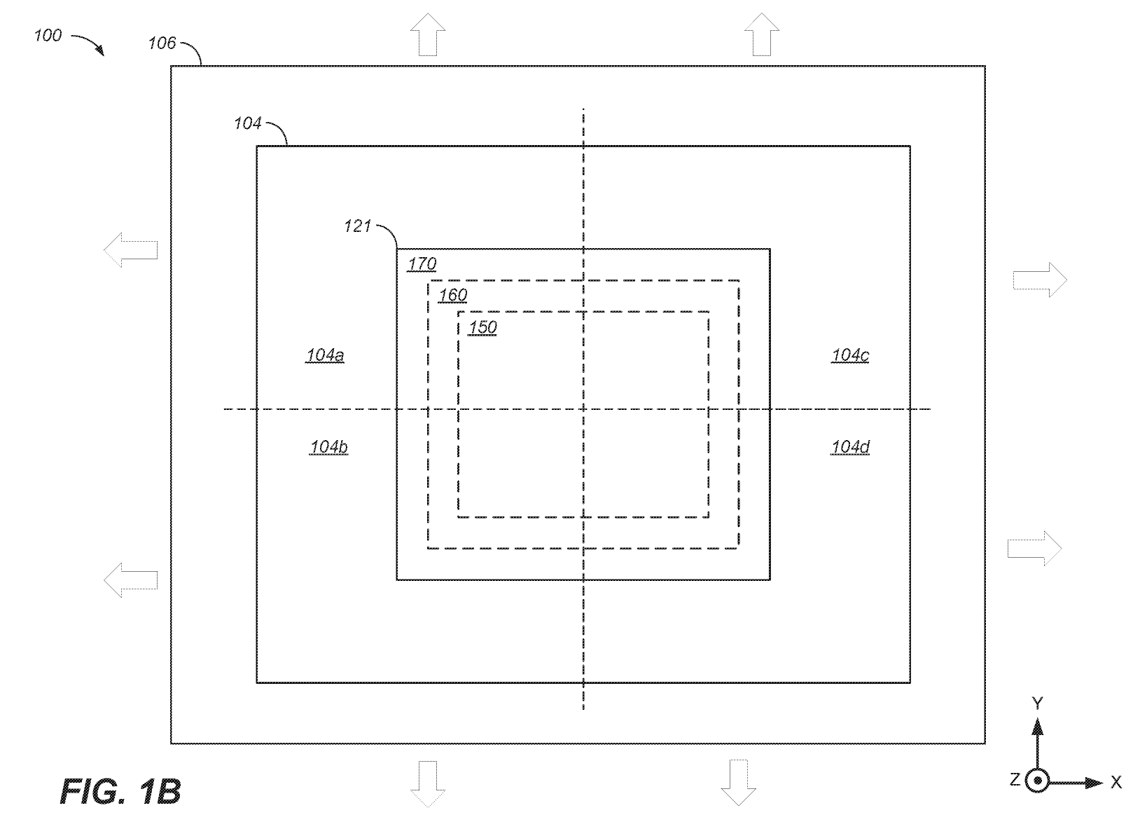

FIG. 1A illustrates an example an assembly 100 that includes an IC package 101 and a printed circuit board (PCB) 106. The IC package 101 includes an IC chip 102, a substrate 104, and a mixed-pitch BGA 108. In some implementations, the IC package 101 may also include a heat sink (not shown) and/or other suitable components. In general, the IC package 101 and the PCB 106 are mechanically and electrically connected using the mixed-pitch BGA 108. The IC package 101 in the assembly 100 may be any suitable packaged device or a part of a device or a part of a system. For example, the IC package 101 may be a component of a network switch in a network system.

The IC chip 102 may be a silicon die that includes circuitry for one or more specific functions. For example, the IC chip 102 may be a transmitter that generates, modulates, and outputs multi-channel signals, or a receiver that receives and detects multi-channel signals from an external data path. The IC chip 102 may include SerDes I/O pins of a networking switch, where data may be communicated using differential pairs.

The substrate 104 includes circuitry that establishes electrical connections between the IC chip 102 and the PCB 106. The substrate 104 may be formed by a multilayer lamination of ground layers, power layers and/or signal layers (not shown in FIG. 1A). The IC chip 102 may be flip-chip bonded or wire-bonded to the substrate 104. The substrate 104 and the PCB 106 include bond pads that are formed according to the arrangement of the mixed-pitch BGA 108. The substrate 104 is bonded to the PCB 106 using solder balls of the mixed-pitch BGA 108.

The PCB 106 includes multiple layers of circuitry and vias to establish electrical connections with the IC package 101 using the mixed-pitch BGA 108. For example, as illustrated in FIG. 1A, the PCB 106 may include M layers of circuitry, including signal layers 112, 114, 116, and 118, where M is any positive integer. Although not shown in FIG. 1A, in some implementations, ground layers that are connected to a reference voltage may be stacked above and below a signal layer (e.g., 112) to electrically separate two signal layers, e.g., 112 and 118, from each other. Each layer may include circuitry for one or more specific functions. For example, the layer 112 may include conductive traces that provide a route for a pair of high-speed differential signals between the substrate 104 and the PCB 106 through vias 132a and 132b and respective BGA solder balls 122a and 122b. As another example, the layer 112 may further include conductive traces that provide a different route for another pair of high-speed differential signals between the substrate 104 and the PCB 106 through vias 134a and 134b and respective BGA solder balls 124a and 124b. As another example, the layer 114 may include conductive traces that provides a power signal to the substrate 104 through a via 136 and a corresponding BGA solder ball 126. As another example, the layer 116 may include conductive traces that provides a ground signal to the substrate 104 through a via 138 and a corresponding BGA solder ball 128.

In some implementations, non-conductive back-drilled holes may be formed by a process called back drill or counter-boring to remove a stub portion of a via. The non-conductive back-drilled holes eliminate an unused portion of the vias called stub, which reduce signal reflection induced within the vias and improve the quality of the high speed signals. For example, back-drilled holes 142a and 142b may be formed by removing a portion of the vias 132a and 132b, respectively to improve the quality of the high speed differential signals propagated in the PCB layer 112. Due to the drill depth tolerance, there may be a very short via stub remaining after back drill.

In some implementations, the formation of the back-drilled holes may also reduce or eliminate a crosstalk between differential pairs. For example, by forming the back-drilled holes 142a and 142b, a crosstalk between differential signals propagated in the PCB layer 112 and differential signals propagated in the PCB layer 118, 119, or 120 is reduced or eliminated because no electrical signal from the vias 122a and 122b could couple into the PCB layers 118, 119, and 120. Similarly, by forming the back-drilled holes 144a and 144b, a crosstalk between differential signals propagated in the PCB layer 118 and differential signals propagated in the PCB layer 119 or 120 is reduced or eliminated because no electrical signal from the vias 133a and 133b could couple into the PCB layers 119 and 120.

FIG. 1A illustrates a signal routing layer assignment in conjunction with the back drill to prevent the coupling between high speed differential traces on one layer and other high speed differential traces on other layers. Specifically, the example assembly 100 shows a signal routing layer assignment where the closer the high speed signal BGA balls are to the center of the IC chip 102, the lower the signal layer on the PCB 106 is assigned to the corresponding high speed differential traces. For example, the high speed signal BGA balls 152a and 152b are to the center of the IC chip 102 than the high speed signal BGA balls 122a and 122b. Accordingly, the high speed differential traces associated with the high speed signal BGA balls 152a and 152b are assigned to a lower signal PCB layer 120, whereas the high speed differential traces associated with the high speed signal BGA balls 122a and 122b are assigned to a higher signal PCB layer 112.

The mixed-pitch BGA 108 includes mixed-pitch solder balls that after being soldered, e.g., heated, provide a mechanical and electrical coupling between the substrate 104 and the PCB 106. The mixed-pitch BGA 108 includes solder balls with more than one pitch, such that the overall BGA density of the IC package 101 may be increased without negatively impacting the high speed performance of the IC package 101.

Referring to FIG. 1B, which illustrates a top view, i.e., the x-y view, of the assembly 100, the BGA solder balls (not shown) of the mixed-pitch BGA 108 are covered under the substrate 104. In a conventional BGA, an area 121 that is centered around the IC chip 102 typically includes BGA solder balls that provide power signals, and/or GND signals, and/or design for testability (DFT) signals. In some implementations, the area 121 may be within the perimeter of the IC chip 102. In some other implementations, the area 121 may extend outside the perimeter of the IC chip 102. As an example, if the die size of the IC chip 102 is 20 mm by 20 mm, and if the BGA pitch is 1 mm, a count of BGA solder balls under the area covered by the IC chip 102 may be calculated using equation (1) above:

$$BGA Count ( conventional ) = \frac{( 20 - 1 ) \cdot ( 20 - 1 )}{{1}^{2}} = 361 , \qquad ( 2 )$$

where the 361 BGA solder balls provide power/GND/DFT signals between the substrate 104 and the PCB 106.

The BGA solder balls (not shown here) for connecting to high speed signals, e.g., differential pairs, are typically arranged in areas 104a-104d that are outside of the area 121. Referring back to FIG. 1A, in some implementations, vias for transmitting high speed differential signals, e.g., 132a/132b and 133a/133b, may be routed to different layers, e.g., 112 and 118, of the PCB 106.

Referring back to FIG. 1B, the BGA solder balls (not shown here) for high speed signals in the area 104a are typically routed to exit the PCB 106 in the −x or in the +y direction. The BGA solder balls for high speed signals in the area 104b are typically routed to exit the PCB 106 in the −x or in the −y direction. The BGA solder balls for high speed signals in the area 104c are typically routed to exit the PCB 106 in the +x or in the +y direction. The BGA solder balls for high speed signals in the area 104d are typically routed to exit the PCB 106 in the +x or in the −y direction.

As described above, in a conventional BGA, the area covered by the IC chip 102, e.g., the area 121, does not include BGA solder balls for high speed signals. Therefore, a crosstalk between high-speed signals is not an issue within the boundary of the IC chip 102. In some implementations, a denser power BGA solder balls within the boundary of the IC chip 102 may even be preferable because it prevents electro-migration and reduces voltage drops. Therefore, in a mixed-pitch BGA, e.g., the mixed-pitch BGA 108, a pitch for BGA solder balls in the area 121 may be reduced from a standard pitch P1, e.g., 1 mm, to a reduced pitch P2, e.g., 0.95 mm, to yield denser BGA solder balls. Importantly, even if the pitch in a region of a package may be reduced, a size of the BGA solder balls across the entire package should maintain the same or substantially the same because two regions with mixed pitches need to stay coplanar with each other. In general, for each different BGA pitch, there is a corresponding BGA ball size range according to the industry standards.

Using the previous example, assuming that the pitch between the BGA solder balls under the area 121 may be reduced from 1 mm to 0.95 mm, more BGA solder balls may be arranged in the area 121, i.e., areas 150, 160, and 170:

$$BGA Count ( mixed \text{-} pitch ) = \frac{( 20 - 1 ) \cdot ( 20 - 1 )}{{0.95}^{2}} = 400 , \qquad ( 3 )$$

which is ˜39 more BGA solder balls than the case with a pitch of 1 mm, e.g., the 361 BGA solder balls determined from equation (2).

As illustrated in FIG. 1B, with a reduced pitch, the BGA solder balls that provide power/GND/DFT signals, e.g., the 361 BGA solder balls determined from equation (2), may be condensed to the area 150. Thus, more BGA solder balls may be added to the areas 160 and 170.

In some implementations, BGA solder balls with a reduced pitch, i.e., P2, may be arranged in both the areas 160 and 170. For example, additional BGA solder balls for power signals may be added to the areas 160 and 170 with a reduced pitch of 0.95 mm. As another example, additional BGA solder balls for power signals may be added to the area 160, and additional BGA solder balls for high speed differential pairs may be added to the 170 with a reduced pitch of 0.95 mm. As the result, more power/GND/DFT signals and/or high speed differential pairs may be connected between the IC package 101 and the PCB 106.

In some implementations, BGA solder balls with the reduced pitch, i.e., P2, may be arranged in the area 160 while BGA solder balls with the standard pitch, i.e., P1, may be arranged in the area 170. For example, additional BGA solder balls for high speed differential pairs may be added to the 160 with a reduced pitch of 0.95 mm, and additional BGA solder balls for high speed differential pairs may be added to the 170 with a standard pitch of 1 mm. As the result, more power/GND/DFT signals and/or high speed differential pairs may be connected between the IC package 101 and the PCB 106.

In some implementations, BGA solder balls with a standard pitch, i.e., P1, may be arranged in the areas 160 and 170. For example, additional BGA solder balls for power/GND/DFT signals and/or high speed differential pairs may be added to the areas 160 and 170 with a standard pitch of 1 mm. As the result, more power/GND/DFT signals and/or high speed differential pairs may be connected between the IC package 101 and the PCB 106.

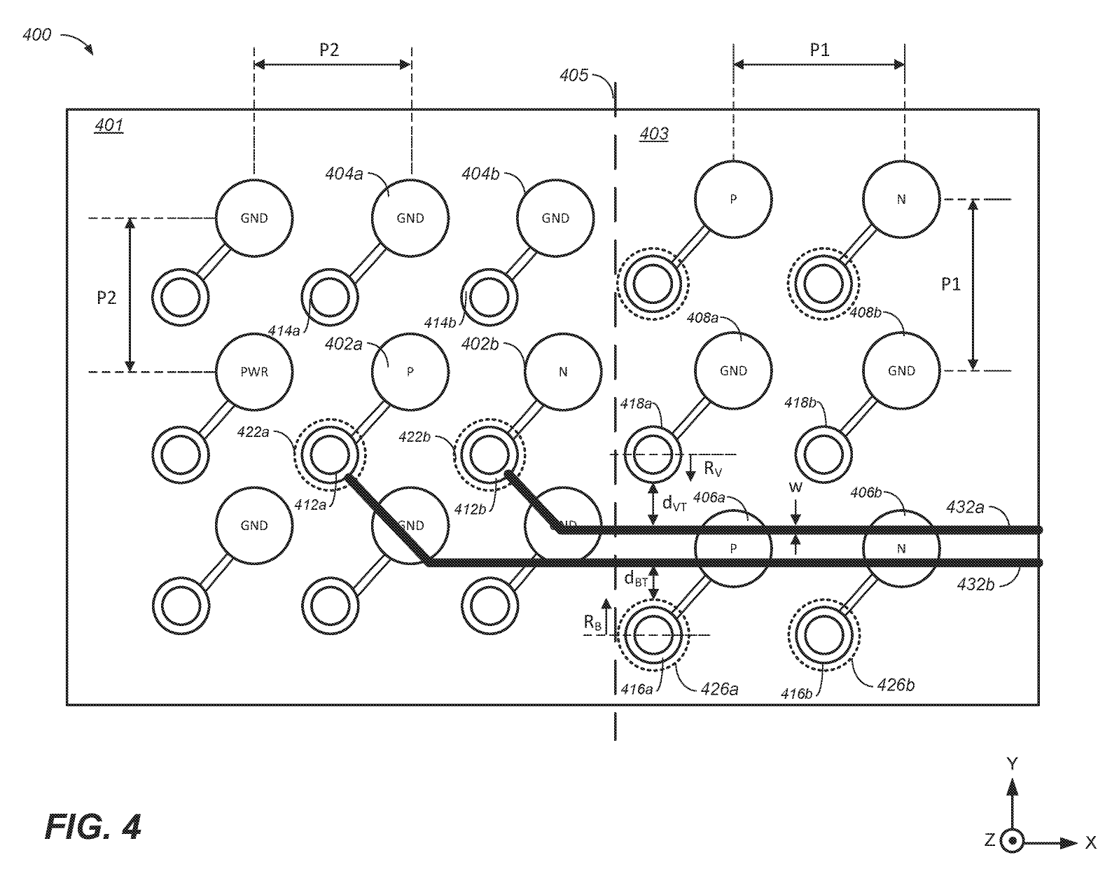

As described in more detail in FIG. 4, one or more differential signal pairs with a reduced BGA pitch may be added to the area 160 or 170 without negatively impacting the high speed performance of the IC package 100. The BGA solder balls for the one or more differential signal pairs with a reduced BGA pitch may be arranged outside or within a perimeter of the IC chip 102.

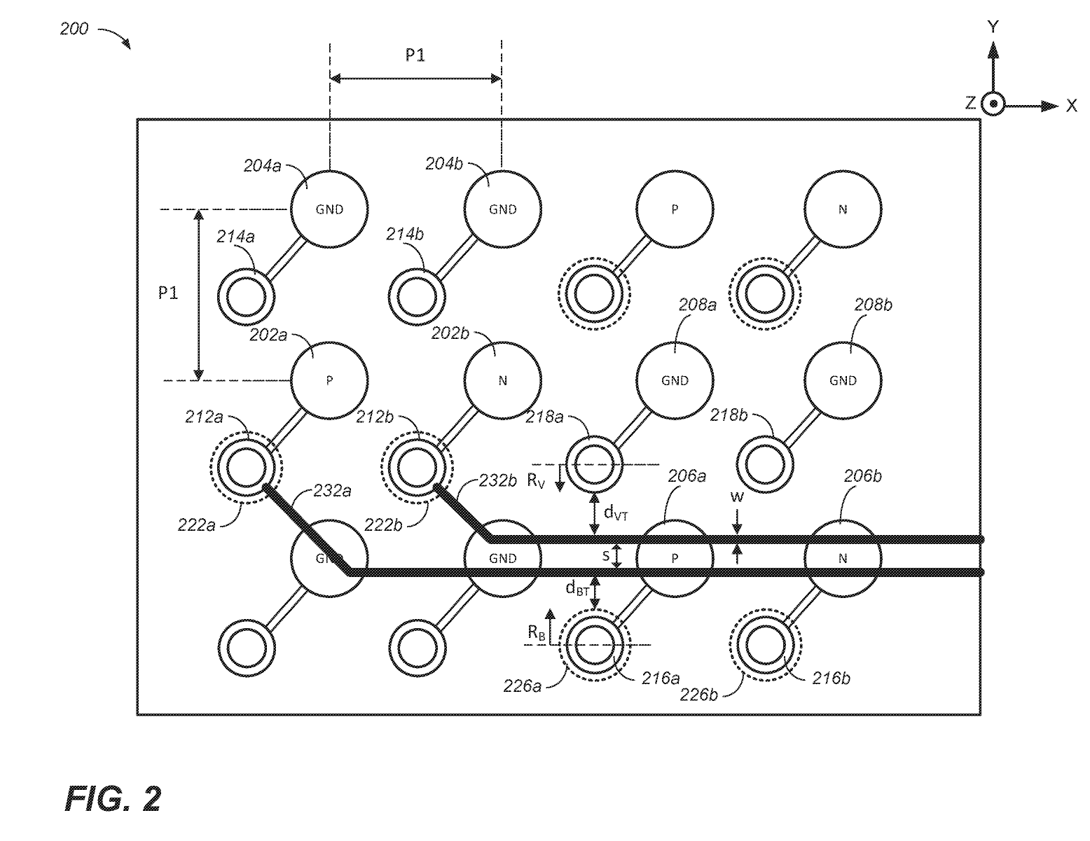

FIG. 2 illustrates an example PCB region 200 having a standard BGA pitch P1, where the PCB region 200 is outside the area 121. In general, the PCB region 200 includes bond pads for establishing electrical connections with multiple pairs of differential signals through a mixed-pitch BGA. The PCB region 200 may be bonded to a region of the area 104d as described above in reference to FIG. 1B, for example. In this example, the bond pads are arranged on intersections of a square or a rectangular grid having a standard pitch, i.e., orthogonally arranged along the X and Y axes.

In this example, the PCB region 200 includes a bond pad 202a for a positive signal of a first differential signal pair, a bond pad 202b for a negative signal of the first differential signal pair, and bond pads 204a and 204b for a ground signal for the first differential signal pair. The bond pads 202a, 202b, 204a, and 204b are connected to conductive vias 212a, 212b, 214a, and 214b, respectively. Back-drilled holes 222a and 222b are formed from the back of the PCB region 200 to reduce reflections for the conductive vias 212a and 212b, respectively.

The PCB region 200 further includes a bond pad 206a for a positive signal of a second differential signal pair, a bond pad 206b for a negative signal of the second differential signal pair, and bond pads 208a and 208b for a ground signal for the second differential signal pair. The bond pads 206a, 206b, 208a, and 208b are connected to conductive vias 216a, 216b, 218a, and 218b, respectively. Back-drilled holes 226a and 226b are formed from the back of the PCB region 200 to reduce reflections for the conductive vias 216a and 216b, respectively.

Conductive signal traces 232a and 232b for the first differential signal pair may be routed on a layer of a PCB, as described in FIG. 1A. In some implementations, to avoid violating a PCB design for manufacturability (DFM) rule, the standard pitch P1 needs to be greater than a signal routing spacing threshold defined as:

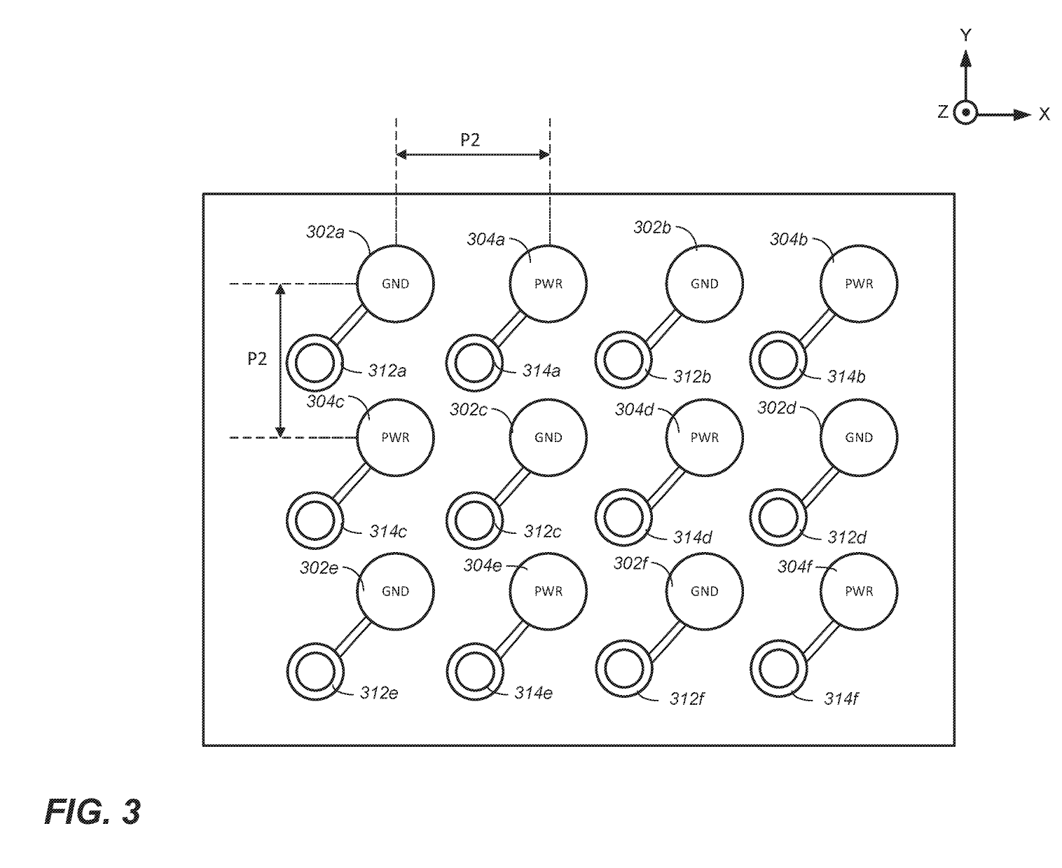

Threshold=R_{V}+d_{VT}+2·w+s+d_{BT}+R_{B} (4),

where R_{V} is the radius of the conductive via 218a, d_{VT} is the minimum distance between the conductive via 218a to the conductive trace 232b, w is the width of the conductive trace 232a/232b, s is the distance between the conductive trace 232a and the conductive trace 232b, d_{BT} is the minimum distance between the conductive trace 232a and the back-drilled hole 226a, and R_{B} is the radius of the back-drilled hole 226a. As an example, if R_{V} is 4 mil, d_{VT} is 8 mil, w is 4 mil, s is 4 mil, d_{BT} is 8 mil, and R_{B} is 8 mil, the threshold will be 40 mil, which corresponds to 1.016 mm. Therefore, with a standard pitch of 1 mm, there may still be a minor PCB DFM rule violation, but may be acceptable to most of the PCB manufacturers. Another alternative way to meet the PCB DFM rule is to reduce the differential pair spacing slightly over a very small segment at the location(s) where the DFM rule is violated, e.g., between the via 218a and the back-drilled hole 226a, so as to completely meet the minimum trace to back drill requirement. If the pitch of the PCB region 200 is reduced to far below 40 mil, e.g., 37.4 mil or 0.95 mm, the DFM rule violations may be unacceptable for the PCB manufacturers. However, the reduced pitch would be fine for power/GND/single-ended low-speed I/O signals as illustrated in FIG. 3, or for an inner-most differential signal pair as illustrated in FIG. 4.

FIG. 3 illustrates an example PCB region 300 having a reduced BGA pitch P2, where the PCB region 300 is within a perimeter of the area 121. In general, the PCB region 300 includes bond pads for establishing electrical connections with multiple power/GND/DFT signals through a mixed-pitch BGA. The PCB region 300 may be bonded to a region of the area 150 as described above in reference to FIG. 1B, for example. In this example, the bond pads are arranged on intersections of a square or a rectangular grid having a reduced pitch, i.e., orthogonally arranged along the X and Y axes.

In this example, the PCB region 300 includes bond pads 302a-302f for a ground signal and bond pads 304a-304f for a power signal. The bond pads 302a-302f and 304a-304f are connected to conductive vias 312a-312f and 314a-314f, respectively. Since the bond pads 302a-302f and 304a-304f are connected to a DC source, a reduced pitch, e.g., 0.95 mm, would increase the density of the BGA without negatively impacting the performance of the package.

FIG. 4 illustrates an example PCB region 400 having mixed BGA pitches P1 and P2. The PCB region 400 includes two sub-regions 401 and 403 as divided by a dotted line 405. Referring back to FIG. 1B, the sub-region 401 may be in the area 160 while the sub-region 403 may be in the area 170. Alternatively, the sub-region 401 may be in the area 170 while the sub-region 403 may be in the area 104a, 104b, 104c, or 104d. In general, an inner-most differential pair having a reduced BGA pitch may be added to the mixed-pitch BGA without negatively impacting the high speed performance and signal escaping from BGA field constrained by PCB DFM drill to trace design rule because no any other differential pairs would pass the vias and back-drilled holes of the inner-most differential pair in the smaller pitch, e.g., P2, region. In this example, the bond pads in the sub-regions 401 and 403 are arranged on intersections of a square or a rectangular grid having a reduced pitch and a standard pitch, respectively.

Referring to FIG. 4, in this example, the PCB region 400 includes a bond pad 402a for a positive signal of an inner-most differential signal pair having a reduced BGA pitch, a bond pad 402b for a negative signal of the inner-most differential signal pair, and bond pads 404a and 404b for a ground signal for the inner-most differential signal pair. The bond pads 402a, 402b, 404a, and 404b are connected to conductive vias 412a, 412b, 414a, and 414b, respectively. Back-drilled holes 422a and 422b are formed from the back of the PCB region 400 to reduce reflections for the conductive vias 412a and 412b, respectively.

The PCB region 400 further includes a bond pad 406a for a positive signal of a second differential signal pair having a standard BGA pitch, a bond pad 406b for a negative signal of the second differential signal pair, and bond pads 408a and 408b for a ground signal for the second differential signal pair. The bond pads 406a, 406b, 408a, and 408b are connected to conductive vias 416a, 416b, 418a, and 418b, respectively. Back-drilled holes 426a and 426b are formed from the back of the PCB region 400 to reduce reflections for the conductive vias 416a and 416b, respectively.

The PCB region 400 further includes conductive signal traces 432a and 432b. Similar to the discussion in reference to FIG. 2, conductive signal traces 432a and 432b for the inner-most differential signal pair may be routed on a layer of a PCB, as described in FIG. 1A. Although the inner-most differential signal pair have a reduced BGA pitch, the conductive signal traces 432a and 432b may be routed on most lower signal layer on the PCB region 400 and still satisfy the threshold because the second differential signal pair have a standard BGA pitch. Although not shown in FIG. 4, additional inner-most differential signal pairs may be added to the PCB along the ±Y direction. Accordingly, using the mixed-pitch BGA, one or more differential signal pairs may be added to the PCB without negatively impacting the high speed performance.

While this specification contains many specifics, these should not be construed as limitations, but rather as descriptions of features specific to particular embodiments. Certain features that are described in this specification in the context of separate embodiments may also be implemented in combination in a single embodiment. Conversely, various features that are described in the context of a single embodiment may also be implemented in multiple embodiments separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination. Various implementations may have been discussed using two-dimensional cross-sections for easy description and illustration purpose. Nevertheless, the three-dimensional variations and derivations should also be included within the scope of the disclosure.

Similarly, while operations are depicted in the drawings in a particular order, this should not be understood as requiring that such operations be performed in the particular order shown or in sequential order, or that all illustrated operations be performed, to achieve desirable results.

Thus, particular embodiments have been described. Other embodiments are within the scope of the following claims. For example, the actions recited in the claims may be performed in a different order and still achieve desirable results.

What is claimed is:

1. An integrated circuit package comprising:
a substrate comprising a multilayer lamination of ground layers, power layers and signal layers;
an integrated circuit chip arranged on the substrate; and
a ball grid array configured to electrically and mechanically connect a printed circuit board and the substrate, the ball grid array comprising:
first solder balls that are periodically separated by a first pitch, wherein two solder balls of the first solder balls connect a first pair of differential signals between the printed circuit board and the substrate; and
second solder balls that are periodically separated by a second pitch that is smaller than the first pitch, wherein two solder balls of the second solder balls connect a second pair of differential signals between the printed circuit board and the substrate,
wherein a size of each solder ball of the first solder balls is substantially equal to a size of each solder ball of the second solder balls.

2. The integrated circuit package of claim 1,
wherein the first solder balls are arranged outside a perimeter of the integrated circuit chip, and
wherein the second solder balls are arranged within the perimeter of the integrated circuit chip.

3. The integrated circuit package of claim 1,
wherein the first solder balls and the second solder balls are arranged outside a perimeter of the integrated circuit chip.

4. The integrated circuit package of claim 1,
wherein one or more solder balls of the second solder balls supply power between the printed circuit board and the integrated circuit chip, and
wherein one or more other solder balls of the second solder balls supply a ground signal between the printed circuit board and the integrated circuit chip.

5. The integrated circuit package of claim 1, wherein the first pitch is larger than a signal routing spacing threshold.

6. The integrated circuit package of claim 5, wherein the signal routing spacing threshold is a sum of (i) a width of a first signal trace carrying a first signal of the first pair of differential signals, (ii) a width of a second signal trace carrying a second signal of the first pair of differential signals, (iii) a minimum separation between the first signal trace and the second signal trace, (iv) a minimum distance from the first signal trace to a first via that is adjacent to the first signal trace, (v) a minimum distance from the second signal trace to a second via that is adjacent to the second signal trace, (vi) a radius of the first via, and (vii) a radius of the second via.

7. The integrated circuit package of claim 6, wherein the first via is a conductive via and the second via is a back-drilled via.

8. The integrated circuit package of claim 5, wherein the second pitch is smaller than the signal routing spacing threshold.

9. The integrated circuit package of claim 1,
wherein the first solder balls are arranged on intersections of a first square or rectangular grid having the first pitch, and
wherein the second solder balls are arranged on intersections of a second square or rectangular grid having the second pitch.

10. An integrated circuit package comprising:
a substrate;
an integrated circuit chip arranged on the substrate; and
a ball grid array configured to electrically and mechanically connect a printed circuit board and the substrate, the ball grid array comprising:
first solder balls that are periodically separated by a first pitch, wherein the first solder balls are arranged outside a boundary of the integrated circuit chip, and wherein the first solder balls are arranged on intersections of a first square grid having the first pitch; and
second solder balls that are periodically separated by a second pitch that is smaller than the first pitch, wherein the second solder balls are arranged within the boundary of the integrated circuit chip, and wherein the second solder balls are arranged on intersections of a second square or rectangular grid having the second pitch,
wherein a size of each solder ball of the first solder balls is substantially equal to a size of each solder ball of the second solder balls.

11. The integrated circuit package of claim 10,
wherein two solder balls of the first solder balls connect a first pair of differential signals between the printed circuit board and the substrate, and
wherein two solder balls of the second solder balls connect a second pair of differential signals between the printed circuit board and the substrate.

12. The integrated circuit package of claim 11, wherein the first pitch is larger than a signal routing spacing threshold.

13. The integrated circuit package of claim 12, wherein the signal routing spacing threshold is a sum of (i) a width of a first signal trace carrying a first signal of the first pair of differential signals, (ii) a width of a second signal trace carrying a second signal of the first pair of differential signals, (iii) a minimum separation between the first signal trace and the second signal trace, (iv) a minimum distance from the first signal trace to a first via that is adjacent to the first signal trace, (v) a minimum distance from the second signal trace to a second via that is adjacent to the second signal trace, (vi) a radius of the first via, and (vii) a radius of the second via.

14. The integrated circuit package of claim 13, wherein the first via is a conductive via and the second via is a back-drilled via.

15. The integrated circuit package of claim 12, wherein the second pitch is smaller than the signal routing spacing threshold.

16. The integrated circuit package of claim 10,
wherein the first solder balls are arranged outside a perimeter of the integrated circuit chip, and
wherein the second solder balls are arranged within the perimeter of the integrated circuit chip.

17. The integrated circuit package of claim 10,
wherein the first solder balls and the second solder balls are arranged outside a perimeter of the integrated circuit chip.

18. An apparatus comprising:
a printed circuit board, comprising:
multilayer lamination of ground layers, power layers and signal layers;
bonding pads for a ball grid array of an integrated circuit package,
wherein the bonding pads comprise:
first periodic bond pads that are periodically separated by a first pitch, wherein two bond pads of the first bond pads are configured to connect a first pair of differential signals between a printed circuit board and the integrated circuit package; and
second periodic bond pads that are periodically separated by a second pitch that is smaller than the first pitch, wherein two bond pads of the second bond pads connect a second pair of differential signals between the printed circuit board and the integrated circuit package.

19. The apparatus of claim 18, further comprising:
an integrated circuit package comprising:
a substrate comprising a multilayer lamination of ground layers, power layers and signal layers;
an integrated circuit chip arranged on the substrate; and
a ball grid array configured to electrically and mechanically connect the printed circuit board and the substrate, the ball grid array comprising:
first solder balls that are periodically separated by the first pitch; and
second solder balls that are periodically separated by the second pitch,
wherein a size of each solder ball of the first solder balls is substantially equal to a size of each solder ball of the second solder balls.

20. The apparatus of claim 18, wherein the first pitch is larger than a signal routing spacing threshold.

21. The apparatus of claim 20, wherein the signal routing spacing threshold is a sum of (i) a width of a first signal trace carrying a first signal of the first pair of differential signals, (ii) a width of a second signal trace carrying a second signal of the first pair of differential signals, (iii) a minimum separation between the first signal trace and the second signal trace, (iv) a minimum distance from the first signal trace to a first via that is adjacent to the first signal trace, (v) a minimum distance from the second signal trace to a second via that is adjacent to the second signal trace, (vi) a radius of the first via, and (vii) a radius of the second via.

22. The apparatus of claim 21, wherein the first via is a conductive via and the second via is a back-drilled via.

23. The apparatus of claim 20, wherein the second pitch is smaller than the signal routing spacing threshold.

24. The apparatus of claim 18,
wherein the first bond pads are arranged on intersections of a first square or rectangular grid having the first pitch, and
wherein the second bond pads are arranged on intersections of a second square or rectangular grid having the second pitch.
